(19) United States
(12) Patent Application Publication
(10) Pub. No.: US 2025/0294795 A1
(43) Pub. Date: Sep. 18, 2025

(54) TRANSISTOR AND METHOD OF FORMING THE SAME

(71) Applicant: Nanyang Technological University, Singapore (SG)

(72) Inventors: Bent Weber, Singapore (SG); Radha Krishnan, Singapore (SG); Sangram Biswas, Singapore (SG)

(21) Appl. No.: 18/859,008

(22) PCT Filed: May 12, 2023
(86) PCT No.: PCT/SG2023/050326

§ 371 Date: Oct. 22, 2024

(30) Foreign Application Priority Data
May 12, 2022 (SG) 10202204996V

(51) Int. Cl. H10D 30/47; H10D 30/01

(52) U.S. Cl. CPC H10D 30/481; H10D 30/017

(57) ABSTRACT

Various embodiments may provide a transistor. The transistor may include a substrate, a first contact electrode and a second contact electrode over the substrate. The transistor may additionally include a two-dimensional semiconductor material layer above the substrate such that the first contact electrode is in contact with a first portion and the second contact electrode is in contact with a second portion of the two-dimensional semiconductor material layer. The transistor may further include a first control gate and a second control gate. The transistor may additionally include a main gate over a third portion of the two-dimensional semiconductor material layer, the third portion between the first portion and the second portion. The transistor may also include a dielectric layer separating the main gate, the first control gate and the second control gate from the two-dimensional semiconductor material layer.

### CROSS-REFERENCE TO RELATED APPLICATION

This application claims the benefit of priority of Singapore application No. 10202204996V filed May 12, 2022, the contents of it being hereby incorporated by reference in its entirety for all purposes.

### TECHNICAL FIELD

Various embodiments of this disclosure may relate to a transistor. Various embodiments of this disclosure may relate to a method of forming a transistor.

### BACKGROUND

Atomically-thin semiconductors, such as a single (mono-) or a few atomic layers of the transition metal dichalcogenides (TMDC) have attracted significant attention in semiconductor processing, owing to large band gaps promising superior electrostatic control. Moreover, the complex interplay of electron (or hole) spin and valley degrees of freedom in these materials have led to proposals for spin-valley quantum bits (qubits) in future spin-based quantum information processing.

However, to exploit the quantum mechanical properties of electrons (or holes) in atomically thin semiconductors, devices are required to be cooled extreme cryogenic temperatures (T<<1 Kelvin (K)). A persistent challenge has been to achieve low-resistance ohmic electrical contacts at such temperatures, especially at very low carrier density (few-electron regime) where quantum effects can be investigated.

### SUMMARY

Various embodiments may provide a transistor. The transistor may include a substrate. The transistor may further include a first contact electrode over the substrate. The transistor may also include a second contact electrode over the substrate. The transistor may additionally include a two-dimensional semiconductor material layer above the substrate such that the first contact electrode is in contact with a first portion of the two-dimensional semiconductor material layer and/or the second contact electrode is in contact with a second portion of the two-dimensional semiconductor material layer. The transistor may further include a first control gate over the two-dimensional semiconductor material layer such that the first portion of the two-dimensional semiconductor material layer is between the first control gate and the first contact electrode. The transistor may further include a second control gate over the two-dimensional semiconductor material layer such that the second portion of the two-dimensional semiconductor material layer is between the second control gate and the second contact electrode. The transistor may additionally include a main gate over a third portion of the two-dimensional semiconductor material layer, the third portion of the two-dimensional semiconductor material layer between the first portion of the two-dimensional semiconductor material layer and the second portion of the two-dimensional semiconductor material layer. The transistor may also include a dielectric layer separating the main gate, the first control gate and the second control gate from the two-dimensional semiconductor material layer.

Various embodiments may relate to a method of forming a transistor. The method may include forming a first contact electrode over a substrate. The method may also include forming a second contact electrode over the substrate. The method may further include forming a two-dimensional semiconductor material layer above the substrate such that the first contact electrode is in contact with a first portion of the two-dimensional semiconductor material layer and/or the second contact electrode is in contact with a second portion of the two-dimensional semiconductor material layer. The method may additionally include forming a first control gate over the two-dimensional semiconductor material layer such that the first portion of the two-dimensional semiconductor material layer is between first control gate and the first contact electrode. The method may also include forming a second control gate over the two-dimensional semiconductor material layer such that the second portion of the two-dimensional semiconductor material layer is between second control gate and the second contact electrode. The method may further include forming a main gate over a channel portion of the two-dimensional semiconductor material layer, the channel portion of the two-dimensional semiconductor material layer between the first portion of the two-dimensional semiconductor material layer and the second portion of the two-dimensional semiconductor material layer. The method may additionally include forming a dielectric layer separating the main gate, the first control gate and the second control gate from the two-dimensional semiconductor material layer.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 is a schematic of a transistor according to various embodiments.

FIG. 2 shows a schematic of a method of forming a transistor according to various embodiments.

FIG. 3 is a schematic showing a transistor according to various embodiments.

FIG. 4 is a schematic showing a transistor according to various other embodiments.

FIG. 5 is a schematic showing a transistor according to yet various other embodiments.

FIG. 6A shows a table comparing the prior contact strategies and the strategy as described herein according to various embodiments.

FIG. 6B shows a semi-logarithmic plot of contact resistance R_{C} (in kilo-ohms micrometers or kΩ·μm) as a function of carrier density n (10¹² per square centimeters or/cm²) comparing various low-temperature contact strategies reported in the literature with the parameters obtained from our device according to various embodiments.

FIG. 7A shows the band alignment schematics of contact formation between contact metal and monolayer molybdenum disulfide (MoS₂).

FIG. 7B shows the formation of charge neutrality level Φ_{CNL} due to defects leading to Fermi-pinning irrespective of the metal work function Φ_{M} mismatch.

FIG. 8 shows (a) a metal-semiconductor interface band diagram of a conventional semiconductor; and (b) a metal-semiconductor interface band diagram of a degenerately doped semiconductor, illustrating the thermionic emission and field emission process.

FIG. 9 shows a schematic of the transistor according to various embodiments.

FIG. 10 shows an outline of a fabricated prototype transistor according to various embodiments.

FIG. 11 shows a plot of channel current I_{SD} (in nano-Amperes or nA) as a function of source-drain bias V_{SD} (in milli-Volts or mV) illustrating the output characteristic of monolayer molybdenum disulfide (MoS₂) device biased with varying control gate voltages (V_{CG}) according to various embodiments.

FIG. 12A shows a plot of the 2-probe conductance G_{2P} (in micro-Siemens or μS) as a function of top gate voltage V_{TG} (in volts or V) illustrating conductance curves at different control gate voltages (V_{CG}) and different fits for extracting contact resistance according to various embodiments.

FIG. 12B shows a schematic illustrating a model for the total resistance of the device according to various embodiments.

FIG. 12C shows a plot of contact resistance 2*R_{C} (in kilo-ohms micrometers or kΩ·μm) as a function of control gate voltage V_{CG} (in volts or V) comparing contact resistances extracted from fitting the resistance model and the 4-probe measurements according to various embodiments.

FIG. 13A shows a plot of conductance G (in quantum conductance or e²/h) as a function of gate voltage V_{TG} (in Volts or V) illustrating the channel trans-conductance curves of the transistor according to various embodiments measured at different temperatures.

FIG. 13B shows plots of the device's differential conductance dI/V in units e²/h×10⁻⁴ as a function of source-drain voltage V_{SD} (in milli electron-Volts or meV) and gate voltage V_{TG} (in volts or V) illustrating finite-bias spectroscopy recorded at a mixing chamber temperature T_{M/C}=30 mK, showing well-defined charge transitions according to various embodiments.

FIG. 13C shows a plot of conductance (in quantum conductance or e²/h×10⁻⁴) as a function of voltage difference α (V_{TG}−V_{TG}^{MAX}) (in milli electron-Volts or meV) illustrating the temperature-dependence of a Coulomb blockade peak used to estimate the electron temperature according to various embodiments (data offset for clarity).

FIG. 13D shows a plot of electronic temperature Tₑₗ (in Kelvins or K) as a function of mixing chamber temperature T_{M/C} (in Kelvins or K) of the dilution refrigerator used to estimate the lowest electron temperature reached according to various embodiments.

FIG. 14A is a plot of top gate voltage V_{TG} (in volts or V) as a function of conductance G (in quantum conductance or e²/h) illustrating the Coulomb blockade peaks for transition D₁ at B=0 and B_{⊥}=2.8 T according to various embodiments.

FIG. 14B is a plot of top gate voltage V_{TG} (in volts or V) as a function of conductance G (in quantum conductance or e²/h) illustrating the Coulomb blockade peaks for transition D₂ at B=0 and B_{⊥}=2.8 T according to various embodiments.

FIG. 14C is a plot of maximum top gate voltage V_{TG}^{MAX} (in volts or V) as a function of out-of-plane magnetic field B_{⊥} (in tesla or T) illustrating the Zeeman shifted ground state transitions in B_{⊥} for D₁ according to various embodiments.

FIG. 14D is a plot of maximum top gate voltage V_{TG}^{MAX} (in volts or V) as a function of out-of-plane magnetic field B_{⊥} (in tesla or T) illustrating the Zeeman shifted ground state transitions in B_{⊥} for D₂ according to various embodiments.

FIG. 15 shows (a-b) plots of ground state energy changes (Zeeman shifts) ΔE (in milli electron-volts or meV) as a function of magnetic field orientation θ (in degrees or deg) illustrating anisotropy of the Zeeman shifts of the ground state transition for D₁ and D₂ as a function of magnetic field orientation according to various embodiments; and (c-d) plots of energy transition ΔE_{∥} (in micro electron-volts or μeV) as a function of in-plane magnetic field B_{∥} illustrating shift of the ground state transitions in an in-plane magnetic field B_{∥} according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the transistors are analogously valid for the other transistors. Similarly, embodiments described in the context of a method are analogously valid for a transistor, and vice versa.

Various embodiments may relate to an electronic device architecture in which reliable tunable low-resistance Ohmic contact to monolayer TMDC semiconductors can be reliably achieved. Various embodiments may be able to address the challenge of achieving low-resistance Ohmic electrical contacts at low temperatures, especially at very low carrier density.

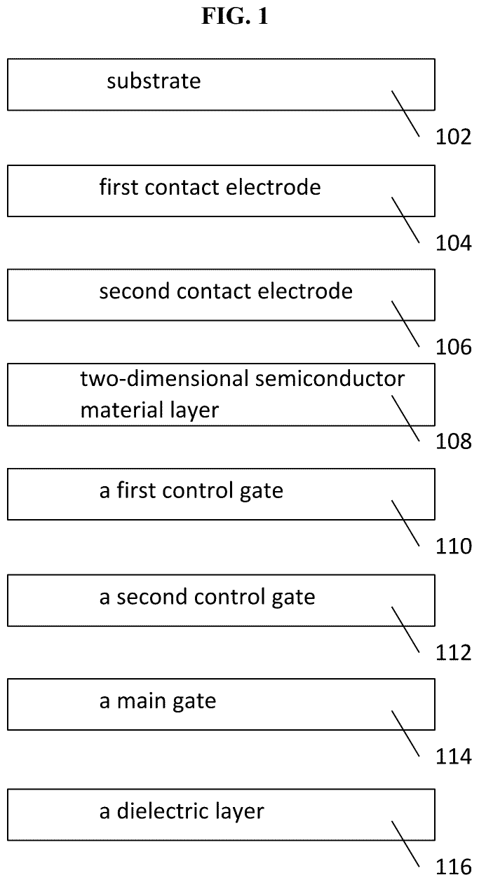

FIG. 1 is a schematic of a transistor according to various embodiments. The transistor may include a substrate 102. The transistor may further include a first contact electrode 104 over the substrate 102. The transistor may also include a second contact electrode 106 over the substrate 102. The transistor may additionally include a two-dimensional semiconductor material layer 108 above the substrate 102 such that the first contact electrode 104 is in contact with a first portion of the two-dimensional semiconductor material layer 108 and/or the second contact electrode 106 is in contact with a second portion of the two-dimensional semiconductor material layer 108. The transistor may further include a first control gate 110 over the two-dimensional semiconductor material layer 108 such that the first portion of the two-dimensional semiconductor material layer 108 is between the first control gate 110 and the first contact electrode 104. The transistor may further include a second control gate 112 over the two-dimensional semiconductor material layer 108 such that the second portion of the two-dimensional semiconductor material layer 108 is between the second control gate 112 and the second contact electrode 106. The transistor may additionally include a main gate 114 over a third portion of the two-dimensional semiconductor material layer 108, the third portion of the two-dimensional semiconductor material layer 108 between the first portion of the two-dimensional semiconductor material layer 108 and the second portion of the two-dimensional semiconductor material layer 108. The transistor may also include a dielectric layer 116 separating the main gate 114, the first control gate 110 and the second control gate 112 from the two-dimensional semiconductor material layer 108.

In other words, the transistor may include a first contact electrode 104 and a second contact electrode 106 over a substrate 102, a two-dimensional semiconductor material layer 108 over the first contact electrode 104 and the second contact electrode 106. The transistor may also include a first control gate 110 over the first portion of the two-dimensional semiconductor material layer 108 and the first contact electrode 104 over the second portion of the two-dimensional semiconductor material layer 108 and the second contact electrode 106. The transistor may also include a main gate 114 over the third portion of the two-dimensional semiconductor material layer 108. A dielectric layer 116 is arranged with the main gate 114, the first control gate 110 and the second control gate 112 on one side of the dielectric layer 116, and the two-dimensional semiconductor material layer 108 on the other side of the dielectric layer 116.

For avoidance of doubt, FIG. 1 seeks to illustrate some features of a transistor according to various embodiments, and is not intended to limit, for instance, the orientation, arrangement, shape, size etc. of the various features.

The third portion of the two-dimensional semiconductor material layer 108 may be referred to as a channel portion. The main gate 114 may alternatively be referred to as top gate (TG).

The two control gates 110, 112 may allow for control of the charge carriers travelling in the two-dimensional semiconductor material layer 108 independently from the main gate 114. Suitable voltages may be applied to the two control gates 110, 112 such that portions of the two-dimensional semiconductor material layer 108 near the contact electrodes 104, 106 may have carrier densities higher (or lower) than the carrier density of the portion of the two-dimensional semiconductor material layer 108 (i.e. the third portion or the channel portion) near the main gate 114. The application of such suitable voltages may be referred to as electrostatic doping or tuning. A higher carrier density of the portions of the two-dimensional semiconductor material layer 108 near the contact electrodes 104, 106 may allow for ohmic contact with the contact electrodes 104, 106, thereby lowering contact resistance. The voltage applied to the main gate 114 may be such that there is a higher or lower charge carrier density of the portion of the two-dimensional semiconductor material layer 108 near the main gate 114 (e.g. the channel portion), which may be useful for applications such as studying of charge carriers, e.g. at low temperatures. For instance, various embodiments may be used for probing of charge transport at extremely low channel carrier densities, sub-threshold, where Coulomb blockade and quantum mechanical effects due to confinement of electrons (or holes) to individual atomic defect states can be observed at electron temperatures lower than 200 mK.

In various embodiments, the transistor may also include one or more local gates such that the two-dimensional semiconductor material layer is over the one or more local gates. The one or more local gates may be used for lateral confinement of charge carriers in the channel portion of the semiconductor, e.g. electrons or holes. The transistor may also include a further dielectric layer in contact with the one or more local gates. The two-dimensional semiconductor material layer may be over the further dielectric layer. The local gates may alternatively be referred to as bottom gates.

In various embodiments, the dielectric layer 116 and the further dielectric layer may include any suitable material with a high enough dielectric constant (k). The dielectric layer 116 and the further dielectric layer may include a monolayer dielectric material (an atomically thin insulating crystal material such as hexagonal boron nitride (hBN)), or a high-k dielectric material/a bulk dielectric material (e.g. hafnium oxide, aluminum oxide silicon oxide, gallium oxide or silicon nitride).

In various embodiments, the two-dimensional semiconductor material layer 108 may include one or more monolayers of a suitable two-dimensional semiconductor material. For instance, the two-dimensional semiconductor material layer 108 may be any atomically thin large band-gap semiconductor, such as a transition-metal dichalcogenide material (e.g. molybdenum disulfide (MoS₂), tungsten diselenide (WSe₂), molybdenum diselenide (MoSe₂), tungsten disulfide (WS₂), rhemium diselenide (ReSe₂) and rhemium disulfide (ReS₂) or related materials), graphene, a Group III-Group V chalcogenide material (e.g. indium selenide (InSe) or gallium selenide (GaSe)), or phosphorene. The material in the two-dimensional semiconductor material layer 108 may also be extended to a wider class of wide bandgap materials such as gallium nitride (GaN) or silicon carbide (SiC).

In various embodiments, the first contact electrode 104 may be a source electrode, while the second contact electrode 106 may be a drain electrode. In various other embodiments, the first contact electrode 104 may be a drain electrode, while the second contact electrode 106 may be a source electrode. In various embodiments, a single contact electrode may be used as an electron reservoir (e.g. for spin-dependent tunneling to obtain quantum coherence (T2) or lifetimes (T1)).

In various embodiments, the first contact electrode 104 and the second contact electrode 106 may include any suitable electrically conductive material. For instance, the first contact electrode 104 and the second contact electrode 106 may include a metal such as gold (Au), platinum (Pt), palladium (Pd), silver (Ag), indium (In), or chromium (Cr). Alternatively, the first contact electrode 104 and the second contact electrode 106 may include an electrically conductive material such as graphene.

In various embodiments, the main gate 114, the first control gate 110 and the second control gate 112 may include any suitable electrically conductive material. For instance, the main gate 114, the first control gate 110 and the second control gate 112 may include a metal such as gold (Au), platinum (Pt), palladium (Pd), silver (Ag), indium (In), or chromium (Cr). Alternatively, the main gate 114, the first control gate 110 and the second control gate 112 may include an electrically conductive material such as graphite.

In various embodiments, the main gate 114 may be arranged laterally between the first control gate 110 and the second control gate 112.

In various other embodiments, a first portion of the main gate 114 may be over a portion of the first control gate 110. A second portion of the main gate 114 may be over a portion of the second control gate 112. The transistor may also include an embedding dielectric layer such that the main gate 114, the first control gate 110 and the second control gate 112 are in contact with the embedding dielectric layer. A first portion of the embedding dielectric layer may separate the main gate 114 from the first control gate 110, while a second portion of the embedding dielectric layer may separate the main gate 114 from the second control gate 112.

In yet various other embodiments, a portion of the first control gate 110 may be over a first portion of the main gate 114. A portion of the second control gate 112 may be over a second portion of the main gate 114. The transistor may also include an embedding dielectric layer such that the main gate 114, the first control gate 110 and the second control gate 112 are in contact with the embedding dielectric layer. A first portion of the embedding dielectric layer separates the main gate 114 from the first control gate 110, while a second portion of the embedding dielectric layer separates the main gate 114 from the second control gate 112.

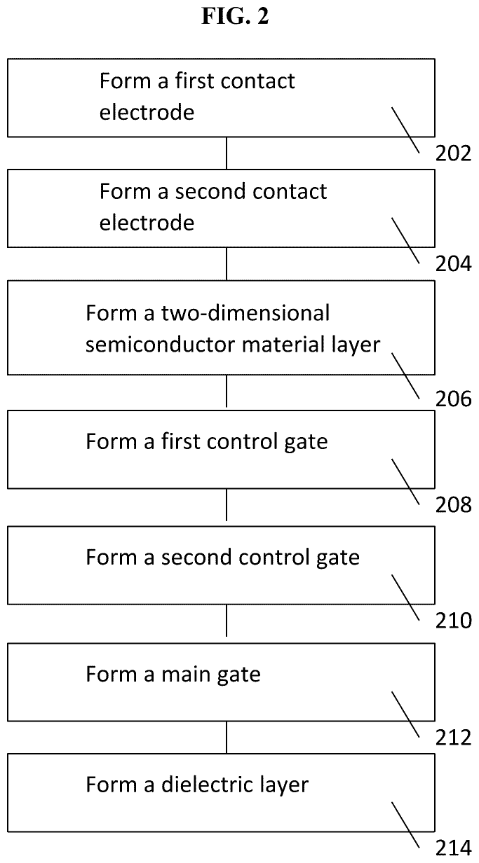

FIG. 2 shows a schematic of a method of forming a transistor according to various embodiments. The method may include, in 202, forming a first contact electrode over a substrate. The method may also include, in 204, forming a second contact electrode over the substrate. The method may further include, in 206, forming a two-dimensional semiconductor material layer above the substrate such that the first contact electrode is in contact with a first portion of the two-dimensional semiconductor material layer and/or the second contact electrode is in contact with a second portion of the two-dimensional semiconductor material layer. The method may additionally include, in 208, forming a first control gate over the two-dimensional semiconductor material layer such that the first portion of the two-dimensional semiconductor material layer is between the first control gate and the first contact electrode. The method may also include, in 210, forming a second control gate over the two-dimensional semiconductor material layer such that the second portion of the two-dimensional semiconductor material layer is between the second control gate and the second contact electrode. The method may further include, in 212, forming a main gate over a channel portion of the two-dimensional semiconductor material layer, the channel portion of the two-dimensional semiconductor material layer between the first portion of the two-dimensional semiconductor material layer and the second portion of the two-dimensional semiconductor material layer. The method may additionally include, in 214, forming a dielectric layer separating the main gate, the first control gate and the second control gate from the two-dimensional semiconductor material layer.

For avoidance of doubt, FIG. 2 seeks to illustrate some steps according to various embodiments, and is not intended to limit the sequence of the various steps.

In other words, the method may include forming the first electrode, the second electrode, the main gate, the first control gate, the second control gate, the two-dimensional semiconductor material layer and the dielectric layer in any appropriate sequence.

In various embodiments, step 202 and step 204 may occur at the same time. The first contact electrode and the second contact electrode may be formed in a same lithographic step.

In various embodiments, the dielectric layer may be formed before forming the main gate, the first control gate and the second control gate.

In various embodiments, step 208 and step 210 may occur at the same time. The first control gate and the second control gate may be formed in a same lithographic step.

In various embodiments may further include forming one or more local gates such that the two-dimensional semiconductor material layer is over the one or more local gates. The method may also include forming a further dielectric layer in contact with the one or more local gates. The two-dimensional semiconductor material layer may be over the further dielectric layer.

In various embodiments, the dielectric layer and the further dielectric layer may include any suitable material with a high enough dielectric constant (k). The dielectric layer and the further dielectric layer may include a monolayer dielectric material (an atomically thin insulating crystal material such as hexagonal boron nitride (hBN)), or a high-k dielectric material/a bulk dielectric material (e.g. hafnium oxide, aluminum oxide, silicon oxide, gallium oxide or silicon nitride).

In various embodiments, the two-dimensional semiconductor material layer may include one or more monolayers of a suitable two-dimensional semiconductor material. For instance, the two-dimensional semiconductor material layer may be any atomically thin large band-gap semiconductor, such as a transition-metal dichalcogenide material (e.g. molybdenum disulfide (MoS₂), tungsten diselenide (WSe₂), molybdenum diselenide (MoSe₂), tungsten disulfide (WS₂), rhemium diselenide (ReSe₂) and rhemium disulfide (ReS₂) or related materials), graphene, a Group III-Group V chalcogenide material (e.g. indium selenide (InSe) or gallium selenide (GaSe)), or phosphorene. The material in the two-dimensional semiconductor material layer may also be extended to a wider class of wide bandgap materials such as gallium nitride (GaN) or silicon carbide (SiC).

In various embodiments, the first contact electrode may be a source electrode, while the second contact electrode may be a drain electrode. In various other embodiments, the first contact electrode may be a drain electrode, while the second contact electrode may be a source electrode. In various embodiments, a single contact electrode may be used as an electron reservoir (e.g. for spin-dependent tunneling to obtain quantum coherence (T2) or lifetimes (T1)).

In various embodiments, the main gate may be arranged laterally between the first control gate and the second control gate.

In various other embodiments, a first portion of the main gate may be over a portion of the first control gate. A second portion of the main gate may be over a portion of the second control gate. The method may also include forming an embedding dielectric layer such that the main gate, the first control gate and the second control gate are in contact with the embedding dielectric layer. A first portion of the embedding dielectric layer may separate the main gate from the first control gate, while a second portion of the embedding dielectric layer may separate the main gate from the second control gate.

In yet various other embodiments, a portion of the first control gate may be over a first portion of the main gate. A portion of the second control gate may be over a second portion of the main gate. The method may also include forming an embedding dielectric layer such that the main gate, the first control gate and the second control gate are in contact with the embedding dielectric layer. A first portion of the embedding dielectric layer separates the main gate from the first control gate, while a second portion of the embedding dielectric layer separates the main gate from the second control gate.

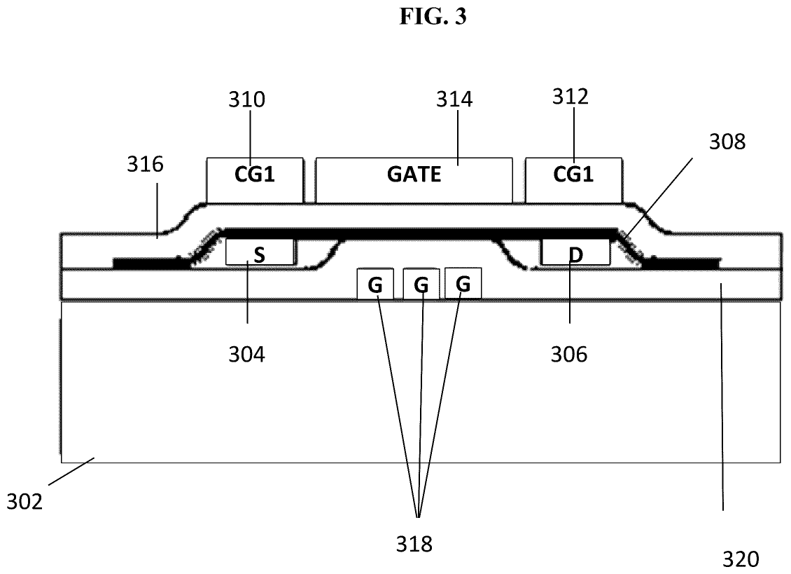

FIG. 3 is a schematic showing a transistor according to various embodiments. The transistor may include a substrate 302. The transistor may further include a first contact electrode 304 over the substrate 302. The transistor may also include a second contact electrode 306 over the substrate 302. While FIG. 3 indicates the first contact electrode 304 is a source (S) electrode and the second contact electrode 306 is a drain (D) electrode, it may be envisioned that the first contact electrode 304 may be a drain (D) electrode and the second contact electrode 306 may be a source (S) electrode. The transistor may additionally include a two-dimensional semiconductor material layer 308 above the substrate 302 such that the first contact electrode 304 is in contact with a first portion of the two-dimensional semiconductor material layer 308 and the second contact electrode 306 is in contact with a second portion of the two-dimensional semiconductor material layer 308. The transistor may further include a first control gate 310 over the two-dimensional semiconductor material layer 308 such that the first portion of the two-dimensional semiconductor material layer 308 is between the first control gate 310 and the first contact electrode 304. The transistor may further include a second control gate 312 over the two-dimensional semiconductor material layer 308 such that the second portion of the two-dimensional semiconductor material layer 308 is between the second control gate 312 and the second contact electrode 306. The transistor may additionally include a main gate 314 over a third portion of the two-dimensional semiconductor material layer 308, the third portion of the two-dimensional semiconductor material layer 308 between the first portion of the two-dimensional semiconductor material layer 308 and the second portion of the two-dimensional semiconductor material layer 308. The transistor may also include a dielectric layer 316 separating the main gate 314, the first control gate 310 and the second control gate 312 from the two-dimensional semiconductor material layer 308. The transistor may also include one or more local gates 318 such that the two-dimensional semiconductor material layer 308 is over the one or more local gates 318. The transistor may further include a further dielectric layer 320 in contact with the one or more local gates 318. The two-dimensional semiconductor material layer 308 may be over the further dielectric layer 320. For the transistor shown in FIG. 3, the main gate 314 may be arranged laterally between the first control gate 310 and the second control gate 312. The main gate 314 may be spaced apart from the first control gate 310 as well as the second control gate 312.

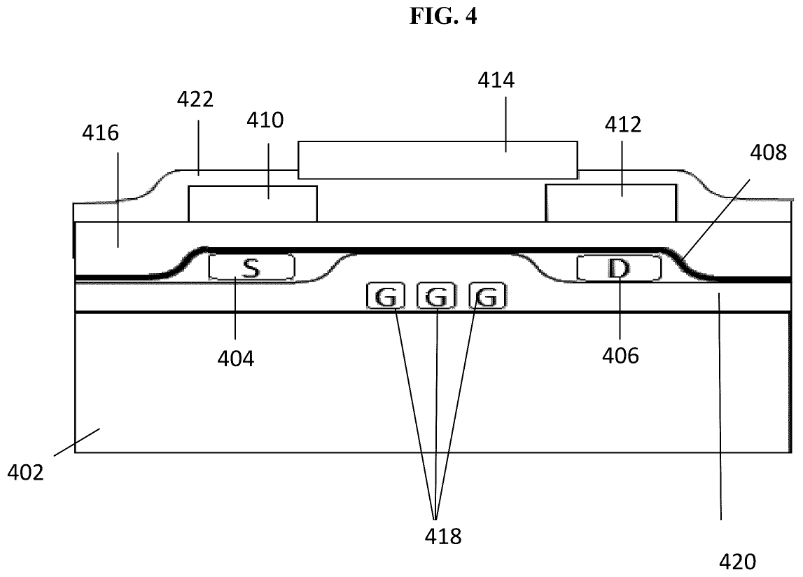

FIG. 4 is a schematic showing a transistor according to various other embodiments. The transistor may include a substrate 402. The transistor may further include a first contact electrode 404 over the substrate 402. The transistor may also include a second contact electrode 406 over the substrate 402. While FIG. 4 indicates the first contact electrode 404 is a source (S) electrode and the second contact electrode 406 is a drain (D) electrode, it may be envisioned that the first contact electrode 404 may be a drain (D) electrode and the second contact electrode 406 may be a source (S) electrode. The transistor may additionally include a two-dimensional semiconductor material layer 408 above the substrate 402 such that the first contact electrode 404 is in contact with a first portion of the two-dimensional semiconductor material layer 408 and the second contact electrode 406 is in contact with a second portion of the two-dimensional semiconductor material layer 408. The transistor may further include a first control gate 410 over the two-dimensional semiconductor material layer 408 such that the first portion of the two-dimensional semiconductor material layer 408 is between the first control gate 410 and the first contact electrode 404. The transistor may further include a second control gate 412 over the two-dimensional semiconductor material layer 408 such that the second portion of the two-dimensional semiconductor material layer 408 is between the second control gate 412 and the second contact electrode 406. The transistor may additionally include a main gate 414 over a third portion of the two-dimensional semiconductor material layer 408, the third portion of the two-dimensional semiconductor material layer 408 between the first portion of the two-dimensional semiconductor material layer 408 and the second portion of the two-dimensional semiconductor material layer 408. The transistor may also include a dielectric layer 416 separating the main gate 414, the first control gate 410 and the second control gate 412 from the two-dimensional semiconductor material layer 408. The transistor may also include one or more local gates 418 such that the two-dimensional semiconductor material layer 408 is over the one or more local gates 418. The transistor may further include a further dielectric layer 420 in contact with the one or more local gates 418. The two-dimensional semiconductor material layer 408 may be over the further dielectric layer 420. A first portion of the main gate 414 may be over a portion of the first control gate 410, while a second portion of the main gate 414 may be over a portion of the second control gate 412. The transistor may include an embedding dielectric layer 422 such that the main gate 414, the first control gate 410 and the second control gate 412 are in contact with the embedding dielectric layer 422. A portion of the embedding dielectric layer 422 may separate the main gate 414 from the first control gate 410, while another portion of the embedding dielectric layer 422 may separate the main gate 414 from the second control gate 412.

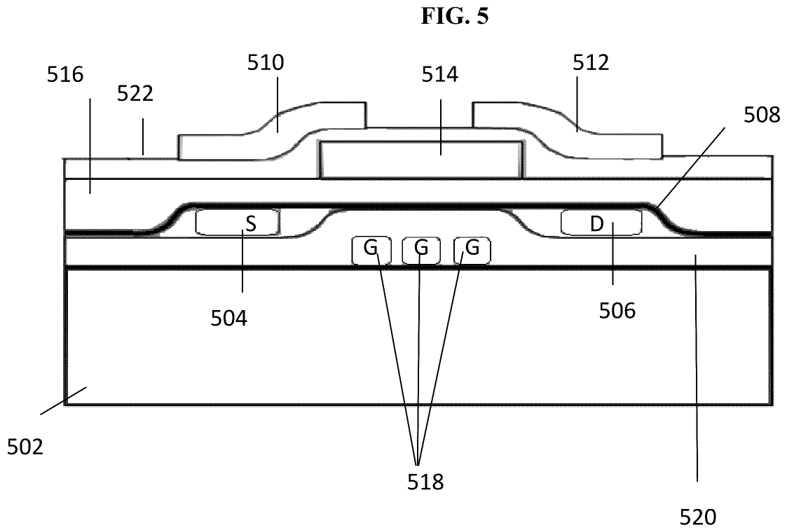

FIG. 5 is a schematic showing a transistor according to yet various other embodiments. The transistor may include a substrate 502. The transistor may further include a first contact electrode 504 over the substrate 502. The transistor may also include a second contact electrode 506 over the substrate 502. While FIG. 5 indicates the first contact electrode 504 is a source (S) electrode and the second contact electrode 506 is a drain (D) electrode, it may be envisioned that the first contact electrode 504 may be a drain (D) electrode and the second contact electrode 506 may be a source (S) electrode. The transistor may additionally include a two-dimensional semiconductor material layer 508 above the substrate 502 such that the first contact electrode 504 is in contact with a first portion of the two-dimensional semiconductor material layer 508 and the second contact electrode 506 is in contact with a second portion of the two-dimensional semiconductor material layer 508. The transistor may further include a first control gate 510 over the two-dimensional semiconductor material layer 508 such that the first portion of the two-dimensional semiconductor material layer 508 is between the first control gate 510 and the first contact electrode 504. The transistor may further include a second control gate 512 over the two-dimensional semiconductor material layer 508 such that the second portion of the two-dimensional semiconductor material layer 508 is between the second control gate 512 and the second contact electrode 506. The transistor may additionally include a main gate 514 over a third portion of the two-dimensional semiconductor material layer 508, the third portion of the two-dimensional semiconductor material layer 508 between the first portion of the two-dimensional semiconductor material layer 508 and the second portion of the two-dimensional semiconductor material layer 508. The transistor may also include a dielectric layer 516 separating the main gate 514, the first control gate 510 and the second control gate 512 from the two-dimensional semiconductor material layer 508. The transistor may also include one or more local gates 518 such that the two-dimensional semiconductor material layer 508 is over the one or more local gates 518. The transistor may further include a further dielectric layer 520 in contact with the one or more local gates 518. The two-dimensional semiconductor material layer 508 may be over the further dielectric layer 520. A portion of the first control gate 510 may be over a first portion of the main gate 514, while a portion of the second control gate 512 may be over a second portion of the main gate 514. The transistor may additionally include an embedding dielectric layer 522 such that the main gate 514, the first control gate 510 and the second control gate 512 are in contact with the embedding dielectric layer 522. A first portion of the embedding dielectric layer 522 may separate the main gate 514 from the first control gate 510, while a second portion of the embedding dielectric layer 522 may separate the main gate 514 from the second control gate 512. A portion of the embedding dielectric layer 522 may separate the main gate 514 from the first control gate 510, while another portion of the embedding dielectric layer 522 may separate the main gate 514 from the second control gate 512.

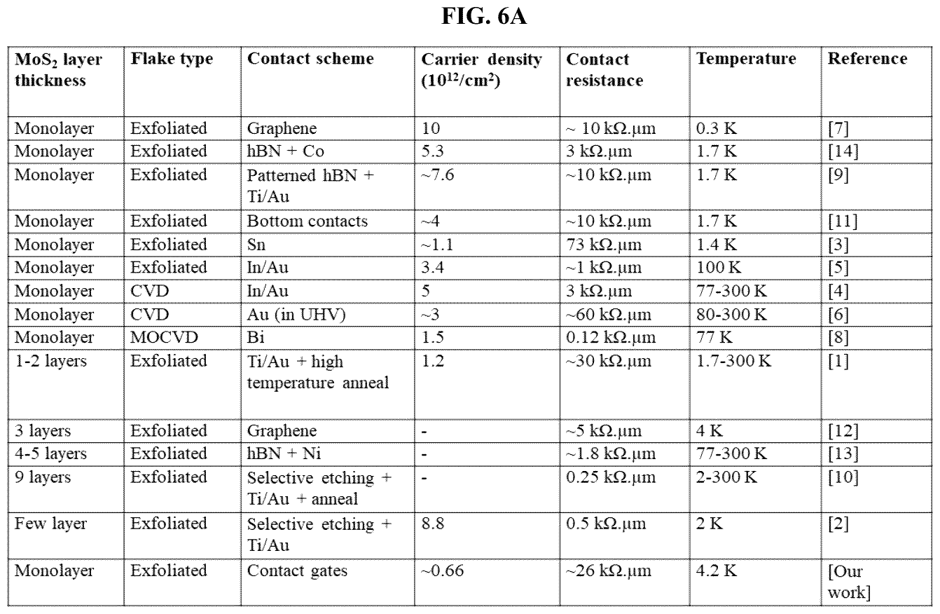

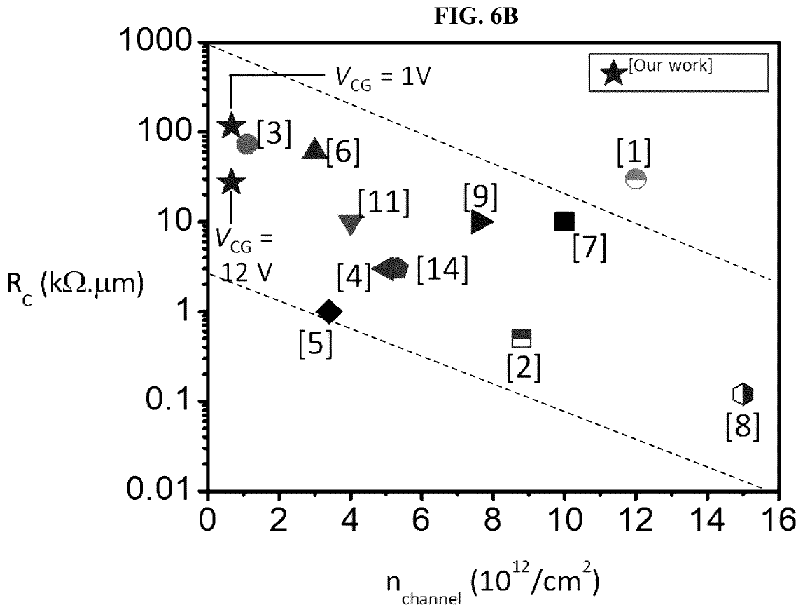

As mentioned above, the two-dimensional semiconductor material layer may be a TDMC material. Semiconducting TMDCs such as MoS₂, WSe₂ etc. are well suited as channel material to their large bandgap (1.5-2.5 eV), which varies depending on the thickness of the TMDCs. This wide-bandgap produces a high on/off ratio, however, large mismatch of the TMDC electron affinity with the work-function of commonly used contact metals, causes a Schottky barrier (SB) to be formed at the TMDC-metal contact interface. This makes it difficult to create low-resistance Ohmic contacts capable of injecting carriers reliably into the TMDC channel. Several recent experimental studies have demonstrated progress in improving MoS₂ contacts, which includes use of metals with low-work-function, doped TMDCs, phase engineering, ionic-liquid gating, and thin interlayer barriers, among others. However, these studies have primarily concentrated on few-layer TMDCs and their room temperature characterization. Making ohmic contacts to a TDMC material such as MoS₂ at low temperatures, particularly for monolayers, and at low carrier densities has remained a major challenge to date. FIG. 6A shows a table comparing the prior contact strategies and the strategy as described herein according to various embodiments.

Prior contact strategies may be broadly based on the following: (1) minimizing SB height by employing contacts metals with proper work function; or (2) reducing metal semiconductor interactions at the interface for minimizing Fermi level pinning.

Contacting strategies based on these approaches include using low-work function contact metals such as titanium (Ti), tin (Sn), indium (In), and gold (Au). Furthermore, semi-metals such as monolayer graphene, bismuth, and monolayer hexagonal boron nitride (hBN) in conjunction with cobalt (Co) have been reported. These strategies have achieved Ohmic contacts to few-and mono-layer MoS₂ at low temperatures from 77 K and even down to 1.8 K. However, achieving ohmic contacts at extremely low channel carrier densities and at milli-Kelvin temperatures remain a challenge in these approaches. FIG. 6B shows a semi-logarithmic plot of contact resistance R_{C} (in kilo-ohms micrometers or kΩ·μm) as a function of carrier density n (10¹² per square centimeters or/cm2) comparing various low-temperature contact strategies reported in the literature with the parameters obtained from our device according to various embodiments. Despite a large spread, it can be seen that the contact resistance has a roughly exponential dependence on carrier density, indicating the need for a high carrier density to realize low-resistance Ohmic contact. The contact resistances obtained in our MoS₂ devices according to various embodiments at 4.2 K are represented by stars, whose extraction are described in detail below. A lowest contact resistance of 26 kΩ·μm at carrier densities of ˜8×10¹²/cm² in the contacts has been measured. Importantly, different from other strategies, the device architecture according to various embodiments may allow for independent tuning of the channel to low carrier density (<1×10¹²/cm²) while keeping a constant high carrier density in the contacts facilitating ohmic contact. This allows the investigation of sub-threshold conduction in MoS₂ down to mK temperatures. The principles to form good contact and the rationale behind our contact strategy according to various embodiments are explained in detail below.

The interface created at the semiconductor-metal junction for charge carrier injection has a significant impact on the electronic transport performance. For a semiconductor-metal junction, a work function mismatch causes a Schottky barrier (SB) at the interface.

Assuming that the interface is ideal i.e. without any disorder or defects, the Schottky barrier height (Φ_{SB}) can be estimated from the Schottky-Mott rule:

$${Φ}_{SB - n} = {Φ}_{M} - χ \qquad ( 1 )$$

$${Φ}_{SB - p} = {E}_{G} + {χ}_{S} - {Φ}_{M} \qquad ( 2 )$$

where Φ_{SB-n} and Φ_{SB-p} are SB for n-type and p-type conduction respectively, Φ_{M} is the work function of the metal, χ_{S} is the semiconductor's vacuum electron affnity i.e. the difference in energy between the conduction band minimum (E_{C}) and the vacuum level (E₀), and E_{G} is its bandgap.

As a consequence of their wide bandgap and low electron affinity, semiconducting TMDCs usually suffer from a substantial work-function mismatch with commonly used contact metals, resulting in a large Schottky barrier (SB) height. For instance, few-layer MoS₂ has an indirect bandgap of 1.2 eV while monolayers have a direct bandgap of 1.8 eV. Bulk MoS₂ has an electron affinity of 4 eV and it is expected to be considerably lower as the thickness decreases due to the increased bandgap. The SB height in monolayers is usually found considerably higher compared to bulk.

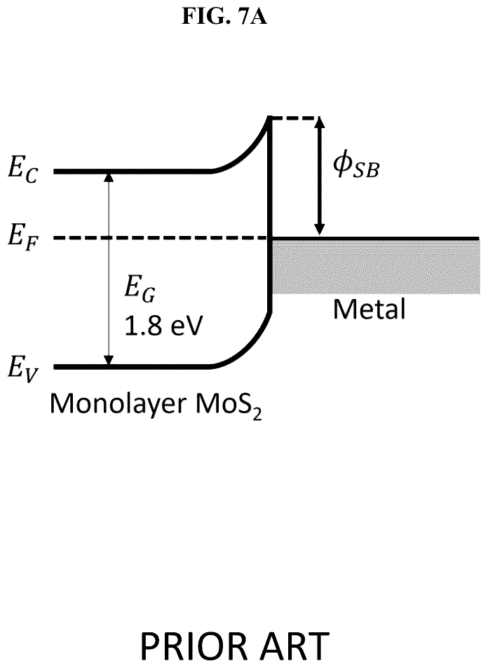

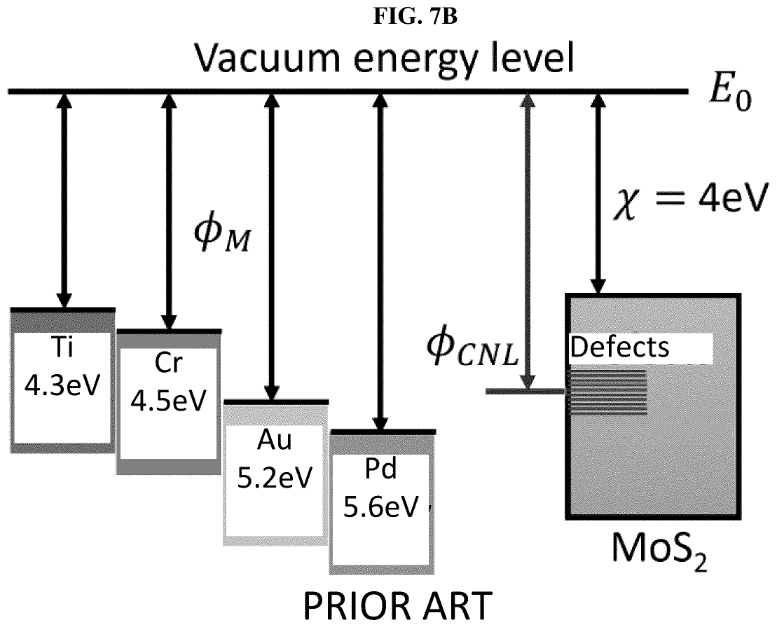

FIG. 7A shows the band alignment schematics of contact formation between contact metal and monolayer molybdenum disulfide (MoS₂). A common strategy for low-resistance Ohmic contacts with negligible SB would be to select a metal with a work function low enough to be near to vacuum electron affinity of the semiconductor (4 eV for MoS₂).

However, experiments have shown that changing the contact metal alone does not significantly alter the Schottky barrier height in MoS₂ devices suggesting Fermi level pinning (FLP) to charge neutrality levels (CNL) from defect states within the bandgap. FIG. 7B shows the formation of charge neutrality level Φ_{CNL} due to defects leading to Fermi-pinning irrespective of the metal work function Φ_{M} mismatch. These defects at the metal-semiconductor interface may occur through either physical or chemical mechanisms and are classified into two groups: metal induced gap states (MIGS) and disorder induced gap states (DIGS). The former arises from physical damage resulting from kinetic energy transfer between metal atoms during contact deposition, and chemical damage due to reactivity of the semiconductor with metal atoms. On the other hand, DIGS arise from adsorbates and intrinsic defects within the semiconductor. Assuming that the Fermi level is pinned at a metal-semiconductor interface state energy (Φ_{IS}), the actual SB height is approximated by the Bardeen limit:

$${Φ}_{SB - n} = S ( {Φ}_{M} - {χ}_{S} ) + ( 1 + S ) {Φ}_{IS} \qquad ( 3 )$$

Here, the parameter S is the pinning factor, which quantifies the strength of the Fermi level pinning and is expressed as

$$S = \vert \frac{d {Φ}_{SB}}{d {Φ}_{M}} \vert \qquad ( 4 )$$

If S=0, the metal-semiconductor interface is described by strong Fermi level pinning, in which the SB height is completely independent of the metal work function, whereas S=1 describes an ideal interface with the SB height determined by Schottky-Mott rule (Equation (1)). In practice, conventional semiconductors rarely attain S near unity. The pinning factors for silicon (Si), gallium arsenide (GaAs), and germanium (Ge), for instance, have been reported to be 0.27, 0.1, and 0.05, respectively. For MoS₂, S=0.11 has been found in multilayers and S=0.15 in monolayers, indicating weak correlation between metal work function and SB height, and suggesting strong FLP. Low work-function metals like titanium (Ti), chromium (Cr) and scandium (Sc) interact strongly with the TMDC layers, giving rise to MIGS and hence FLP. They may therefore not be suitable for achieving low-resistance Ohmic contacts. For the case of titanium/gold (Ti/Au), low contact resistance has been shown after aggressive thermal annealing treatment, but which can have a negative impact on the channel properties due to the formation of sulfur (S) vacancies. Therefore, to reduce the SB height it may be important to choose low-work function contact that also has minimal interactions with the TMDC giving rise to MIGS.

Ohmic contacts have also been realized by using low work-function metals such Sn and In, which have minimal metal invasion into the MoS₂ layers during deposition and minimize Fermi level pinning occurring due to metal induced gap states (MIGS), while also minimizing the SB height. They perform well down to 77 K by minimizing the SB height, however this necessitates specialized deposition equipment capable of cooling the sample holder with cryogens (liquid nitrogen (N₂)) during metal deposition to form a smooth interface with MoS₂. The use of cobalt (Co) in combination with monolayer hexagonal boron nitride (hBN) buffer layer has been reported to produce high-quality n-type contacts at temperatures down to 1.7 K. The hBN buffer layer prevents any direct interaction of metal atoms with MoS₂ layers and thus eliminates the interface states that cause Fermi level pinning. It should be noted that a tunneling barrier is introduced in series with the SB due to the significant band offset of hBN relative to MoS₂ and the increased metal-semiconductor spacing, which leads to an increase in the contact resistance.

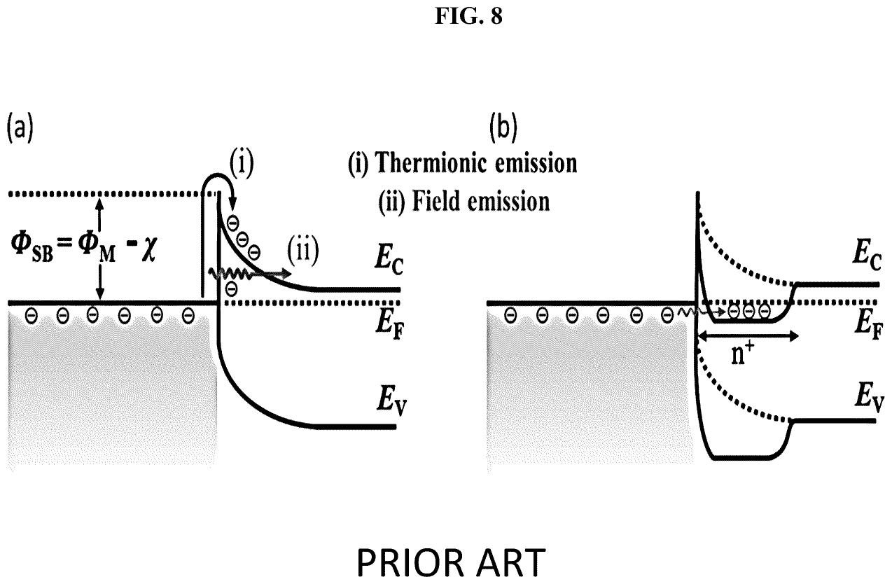

In common semiconductors, e.g. Si and GaAs devices, ion implantation is often used to heavily dope the drain and source contact regions and realize Ohmic contacts. This circumvents the Fermi level pinning issue, as at high doping concentrations the Schottky barrier width is drastically thinned, allowing carriers to easily pass through the barrier via tunneling or field-emission rather than passing over the SB via thermionic emission. FIG. 8 shows (a) a metal-semiconductor interface band diagram of a conventional semiconductor; and (b) a metal-semiconductor interface band diagram of a degenerately doped semiconductor, illustrating the thermionic emission and field emission process. However, controlled chemical doping by implantation or other methods has been challenging in few-layer and mono-layer TMDCs. As the SB width depends on the carrier density, an alternative to chemical doping would be to electrostatically dope the 2D semiconductor using gate electrodes. Graphene has been used to generate robust ohmic contacts to MoS₂ at temperatures down to 300 mK. Owing to the tunability of its Fermi level by electrostatic doping (gating), it allows control over band alignment, and hence the SB height. Also, it allows for vdW integration with the TMDC, thus avoiding Fermi level pinning by MIGS. Such tunable band alignment is however achievable only at large carrier densities.

Various embodiments may provide separate gates to electrostatically dope the channel and contact regions individually, achieving low width normalized contact resistance (˜26 kΩ·μm) contact to MoS₂ at temperature (T)=4.2 K. This approach may allow probing of charge transport at extremely low channel carrier densities, sub-threshold, where Coulomb blockade due to individual atomic defect states can be observed at electron temperatures lower than 200 mK.

In the above techniques, the contact metal is evaporated directly on the TMDC or the buffer interlayer. An alternate strategy that has been reported to reliably yield low resistance contacts is by using atomically flat and clean pre-patterned metal electrodes and laminating the MoS₂ crystal onto them, eliminating FLP due to MIGS by avoiding any direct chemical bonding and induced disorder by evaporation. This technique may enable making low resistance contacts by avoiding contamination from the fabrication process, eliminating the need for sophisticated evaporation or etching processes. For high quality contacts, the base metal may be required to be inert in air in order to facilitate transfer of the TMDC to it without any oxide layer forming. Gold (Au) meets this requirement, and due to its small grain size, provides a very smooth surface which has been reported to form low-resistance n-type contacts to MoS₂. Due to these reasons, gold may be chosen for the pre-patterned contacts.

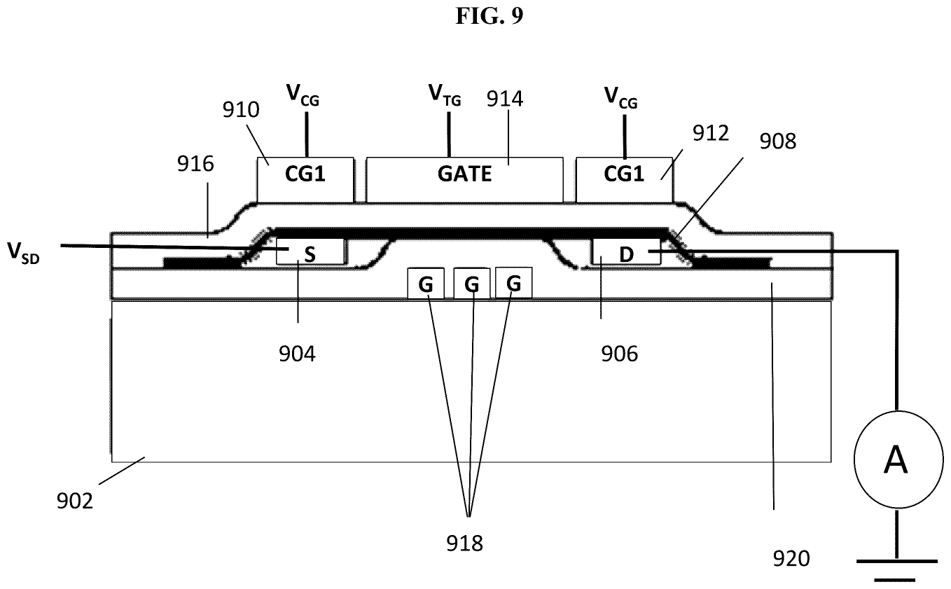

FIG. 9 shows a schematic of the transistor according to various embodiments. The transistor may include a two-dimensional semiconductor material layer 908. The two-dimensional semiconductor material layer 908 may be a TDMC mono-or few layer crystal (e.g. MoS₂ or others), sandwiched between atomically-thin dielectric layers 916, 920 (e.g. h-BN or others). Contact (source (S) and drain (D)) electrodes 904, 906 contact the two-dimensional semiconductor material layer 908 from the bottom within the encapsulated stack. A series of three or more gate electrodes on top (main gate or top gate 914 (GATE), control gates 910, 912 (CG1, CG2)) may control the 2D carrier density in the active layer inducing a 2D electron or hole gas (2DEG or 2DHG) in channel and contact regions independently. Additional gate arrays 918 at the bottom of the stack (G) can be used to further provide additional lateral confinement of the 2DEG or 2DHG (e.g. to form a quantum dot). The additional gate arrays 918 may be formed on or over the substrate 902, and may be separated from the two-dimensional semiconductor material layer 908 via the atomically-thin dielectric layer 920. The combination of two-dimensional semiconductor material layer 908 “bottom contacting”, in combination with spatially separated GATE 914 and CGs 910, 912, may allow for maintaining a very high carrier density in the contact regions, while the channel region may be near threshold or below.

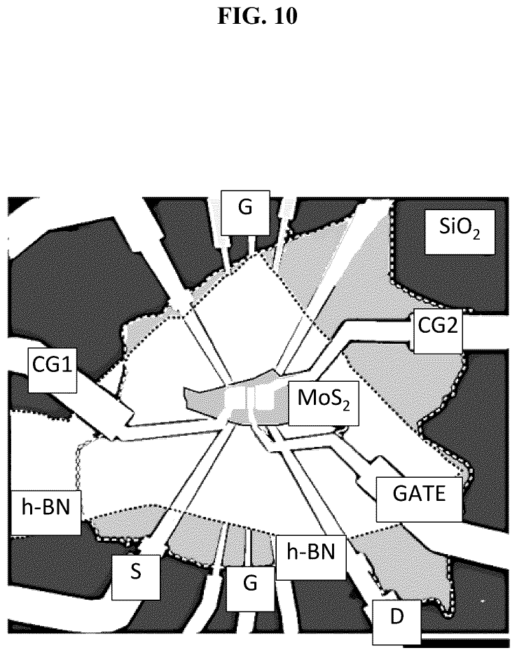

FIG. 10 shows an outline of a fabricated prototype transistor according to various embodiments. The two-dimensional semiconductor material layer includes a few-layers (N≃7) MoS₂ crystal, while the dielectric layers are h-BN. The contact (source S and drain D) electrodes are Ti/Au. As mentioned above, separate metal main or (top) gate (GATE) and contact gates (CG1, CG2) are used to independently tune the electron density in the TMDC transistor channel near threshold, while maintaining a high carrier density within the contact regions, thereby allowing for ohmic contact with contact electrodes 904, 906 to be achieved. As shown in FIG. 9, GATE 914 may be biased with voltage V_{TG}, while the CG1 910, CG2 912 may be biased with voltage V_{CG}. The source-drain bias (between the source electrode 904 relative to the drain electrode 906) is denoted by V_{SD}. The local gate electrodes (G) 918 may be left floating.

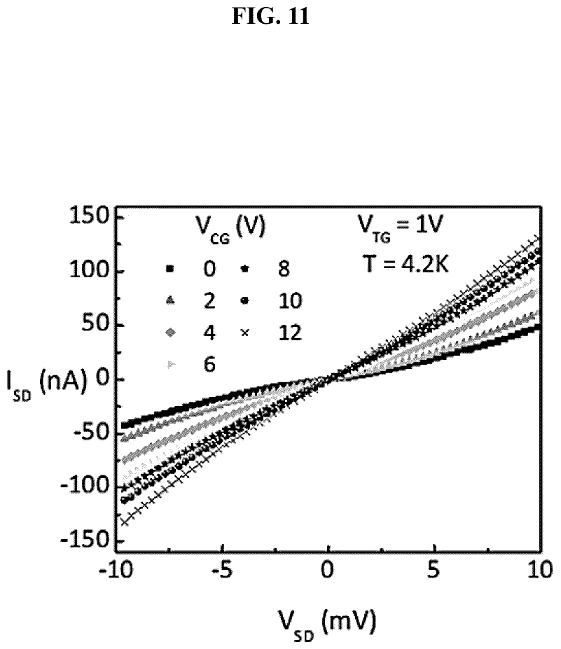

FIG. 11 shows a plot of channel current I_{SD} (in nano-Amperes or nA) as a function of source-drain bias V_{SD} (in milli-Volts or mV) illustrating the output characteristic of monolayer molybdenum disulfide (MoS₂) device biased with varying control gate voltages (V_{CG}) according to various embodiments. The I_{SD}-V_{SD} curves remain highly non-linear when no voltage is applied on the contact gates. However, as V_{CG} is increased, the non-linearity reduces and the I_{SD}-V_{SD} curves display nearly ohmic like nature for V_{CG}=12 V. Thus, the results show that by employing local contact gates it is possible to achieve ohmic contacts without compromising the low carrier density in the MoS₂ channel region.

Having demonstrated that the contact gates can independently tune the carrier density in the contacts, evident by an increase in the overall drive current and ohmic contact, the quality of the electrical contacts is quantified by estimating the contact resistance, R_{C} at T=4.2 K. For this, two methods are employed: (i) fitting the two-probe conductance to a resistance network model and (ii) by performing four-probe measurements. Both yield comparable estimates for R_{C}, ranging between ˜7-100 kΩ for different carrier densities are shown.

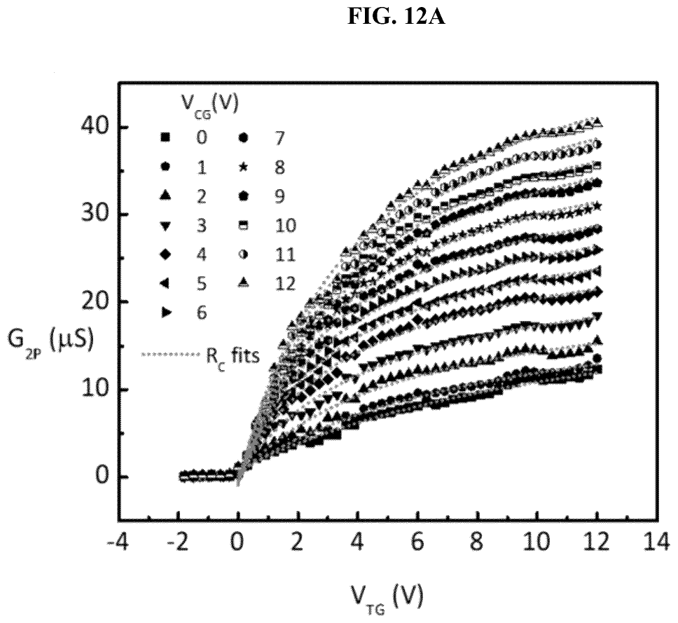

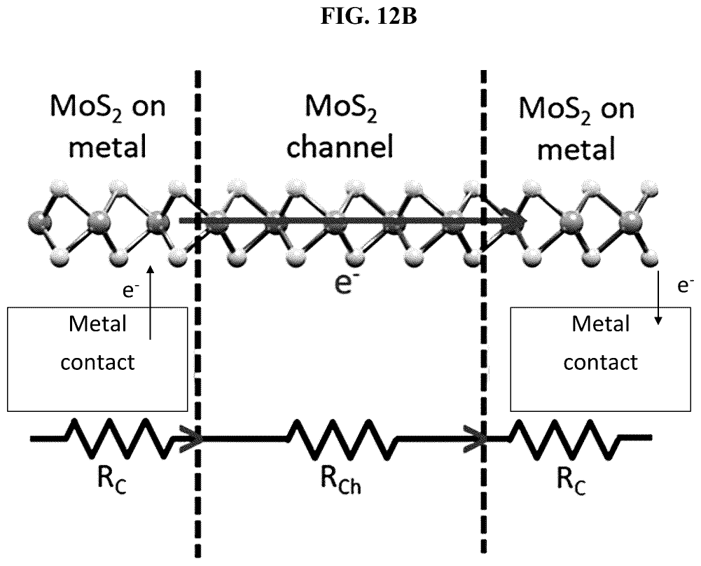

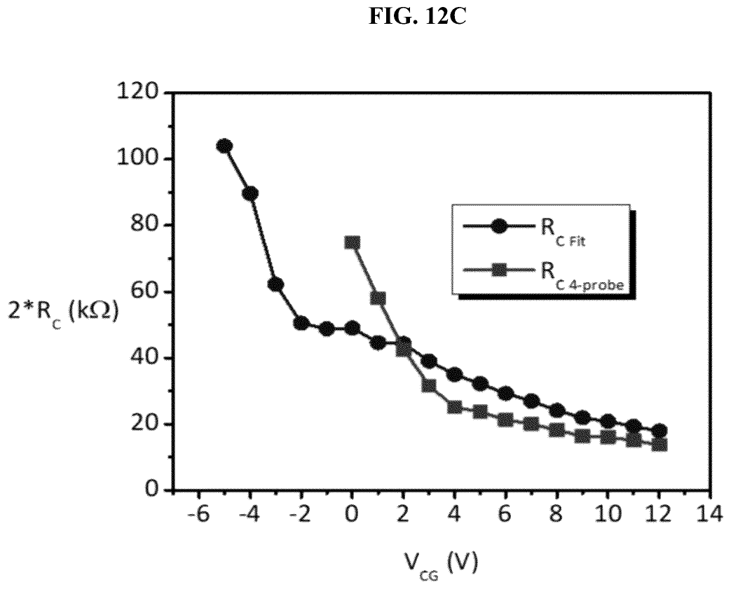

FIG. 12A shows a plot of the 2-probe conductance G_{2P} (in micro-Siemens or μS) as a function of top gate voltage V_{TG} (in volts or V) illustrating conductance curves at different control gate voltages (V_{CG}) and different fits for extracting contact resistance according to various embodiments. FIG. 12A shows five times increase in the conductance at V_{CG}=12V. This clearly indicates increased contact quality due to shrinking of SB width by the contact gates, as a result of independent tuning of the control gate voltages (V_{CG}). Here, it can also be seen that the conductance is not linear in V_{TG} and starts to saturate at large V_{TG} due to contribution from a constant R_{C}.

FIG. 12B shows a schematic illustrating a model for the total resistance of the device according to various embodiments. FIG. 12B shows that the total resistance (Rₜₒₜ) is a sum of the contact resistances at each contact (R_{C}) and the channel resistance (R_{Ch}). Assuming the R_{C} for both source and drain to be the same, Rₜₒₜ is expressed as,

$${R}_{tot} = 2 {R}_{c} + {R}_{Ch} \qquad ( 5 )$$

Both R_{C} (V_{CG}) and R_{Ch} (V_{TG}) are gate voltage dependent. R_{Ch} (V_{TG}) can be further expressed as,

$${R}_{Ch} ( {V}_{TG} ) = \frac{1}{\frac{{WC}_{TG}}{L} μ ( {V}_{TG} - {V}_{TH} )} \qquad ( 6 )$$

where L and W are the length and width of the channel, C_{TG} is the geometric capacitance per unit area of the top gate, and μ is the field effect mobility of electrons in the channel.

By fitting the measured conductance as 1/Rₜₒₜ(V_{TG}), as shown by dashed grey curves (see FIG. 12A), R_{C} at each V_{TG} may be extracted. FIG. 12C shows a plot of contact resistance 2*R_{C} (in kilo-ohms micrometers or kΩ·μm) as a function of control gate voltage V_{CG} (in volts or V) comparing contact resistances extracted from fitting the resistance model and the 4-probe measurements according to various embodiments. FIG. 12C (round markers) shows that R_{C} can be tuned by almost one order of magnitude from ˜55 kΩ at V_{CG}=−6V to ˜9 kΩ at V_{CG}=12V. The areal charge carrier density (nₑ) inducted by the top gate is calculated using the expression

$$\begin{matrix}{n}_{e} = \frac{{C}_{TG} {V}_{TG}}{e} \\ where {C}_{TG} = \frac{{ε}_{0} {ε}_{hBN}}{e}\end{matrix} \qquad ( 7 )$$

is the geometric capacitance per unit area of the top gate and e is electron charge. For a device which has t_{hBN}≈25 nm, nₑ at V_{TG}=1V was estimated to be ˜6.6×10¹¹/cm².

As an independent confirmation of the contact resistance, 4-terminal measurements of the same device may be made to extract a contact resistance

$${R}_{C} = \frac{1}{2} ( {2}_{2 T} - {R}_{4 T} )$$

(square markers in FIG. 12C). There is overall good agreement with the two-probe estimates down to V_{CG}=2V, with a minimum contact resistance of ˜6.5 kΩ at V_{CG}=+12 V, determined from the 4-terminal measurements. Some disagreement at V_{CG}<2 V may arise because of lower fit quality at low V_{CG} as conductance modulations due to the localized states become more pronounced at lower drive current. Therefore, the 4-terminal results likely provide a better estimate of RC at V_{CG}<2 V while both the model described earlier and the 4-terminal measurements provide precise estimates at VCG>2 V. From the measured contact resistances, we calculate the width normalized contact resistance (26 kΩ·μm) for the prototype device by taking the contact width into account. The contact resistances extracted are as shown in FIGS. 6A-B. Including the 4-terminal data, it is found that contact resistances of the device as described herein is significantly lower than any contact resistance reported in literature for carrier densities <1×10¹²/cm² (see FIG. 6A). This is particularly remarkable as these results have been obtained at 4.2K.

Spins confined to semiconductor nanostructures have been investigated extensively for their potential to encode quantum bits (qubits) for quantum information processing. Atomically-thin semiconductors with hexagonal lattices, such as bilayer graphene and the transition metal dichalcogenides (TMDCs), have recently attracted significant attention owing to their additional valley degree of freedom from non-equivalent conduction band minima at the K and K′ points of the Brillouin zone. TMDCs, in particular, offer strong spin-orbit coupling arising from the d-orbitals of the heavy transition metal atom, and a large tunable bandgap. In mono-and odd-numbered layers, broken inversion symmetry combined with time-reversal symmetry can cause the spin and valley degrees to couple, promising approaches to controlling spin-valley states with potentially enhanced spin life-and coherence lifetimes.

Consequently, there has been a significant effort to engineer TMDC-based quantum devices in which few or even single electronic charges and their spin can be isolated and controlled. Electrostatic confinement of electrons to quantum dots has so far been demonstrated in mono-and multi-layers of molybdenum disulfide (MoS₂), tungsten disulfide (WS₂) and tungsten diselenide (WSe₂) and have shown clear signatures of Coulomb blockade in single-charge tunneling. Despite these significant advances in device engineering, however, it has remained challenging to isolate and address individual spin states in the few-electron regime to confirm predictions of their spin-valley character in electron transport spectroscopy. In part, this challenge arises from poorly screened disorder potentials at the extremely low carrier density near threshold, and a large electron effective mass, dictating tight confinement potentials to within a few tens of nanometers.

Different from electrostatically defined quantum dots, spins confined to atomic point defects or shallow dopants have proven to provide tight confinement that is robust to disorder and yields well-separated single particle levels with energy splitting of up to several meV. Defect states have been observed also in TMDC based quantum devices. However, detailed investigations into their spin-valley character have so far been missing.

Resolving individual spin states and probing subtle changes in their state energy from applied electric or magnetic fields requires spectral resolution near the thermal limit (3.5 k_{B}T). Yet, defect-bound spins are usually confined near or below threshold in semiconductor devices. In this extremely low carrier-density regime, it has remained challenging to form transparent electrical contacts which remain low-Ohmic down to the required milliKelvin temperatures.

Various embodiments may address or overcome the abovementioned issues by the use of gate-tunable contacts that remain highly transparent down to the milliKelvin range, allowing tunnelling spectroscopy to be performed with a resolution limited only by electronic temperature of the reservoirs (typically T<200 mK).

The transistor with the gate-tuneable contacts may be a MoS₂ transistor device similar in structure with that shown in FIG. 9. The MoS₂ transistor device was fabricated from a mechanically exfoliated few-layer (˜7) MoS₂ van-der-Waals stack, assembled using a polycarbonate (PC) based dry transfer technique. Local gate electrodes [titanium Ti (3 nm)/gold Au (20 nm)] were prepatterned using standard electron beam lithography and deposition techniques on a 285 nm SiO₂/Si substrate. A thin h-BN flake (thickness ˜30 nm) was subsequently transferred onto the local gates using a PC stamp and annealed in argon/hydrogen (Ar/H₂) atmosphere at 300° C. for 2 hours (h) to remove any contaminants or bubbles. Ti(3 nm)/Au(20 nm) source and drain contacts were subsequently lithographically defined on top of the h-BN layer. Polymer residue was removed using an atomic force microscopy (AFM) tip in contact mode. Subsequently, a h-BN/MoS₂ stack was picked-up using the dry transfer technique and precisely placed on top of the cleaned contact electrodes. This was followed by patterning of Ti(3 nm)/Au(40 nm) top-and contact gates.

All following measurements were performed in a BlueFors LD 250 closed cycle dilution refrigerator, using standard DC measurement techniques.

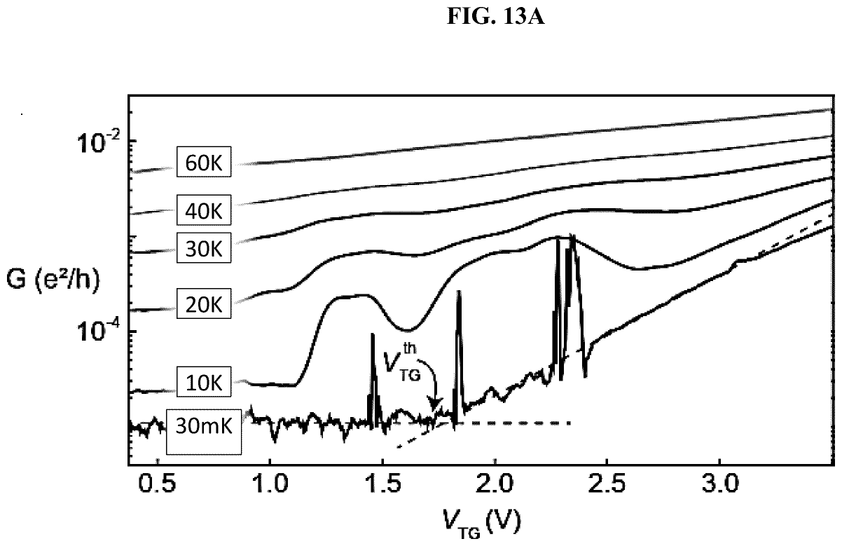

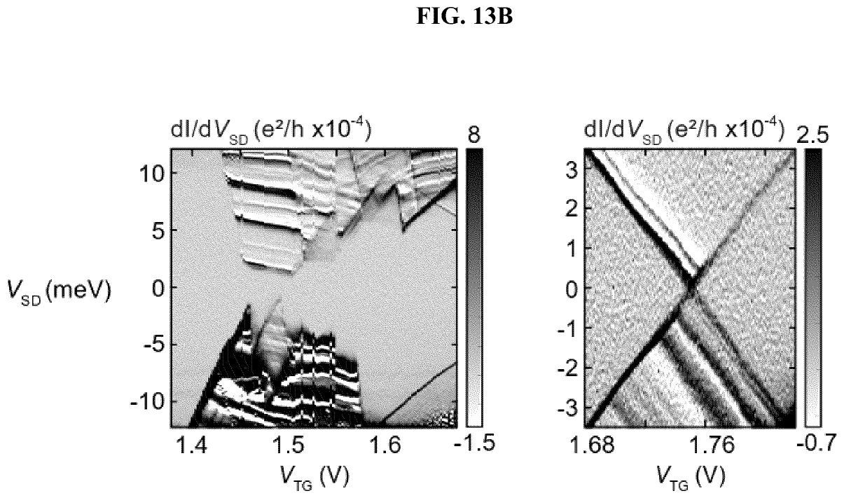

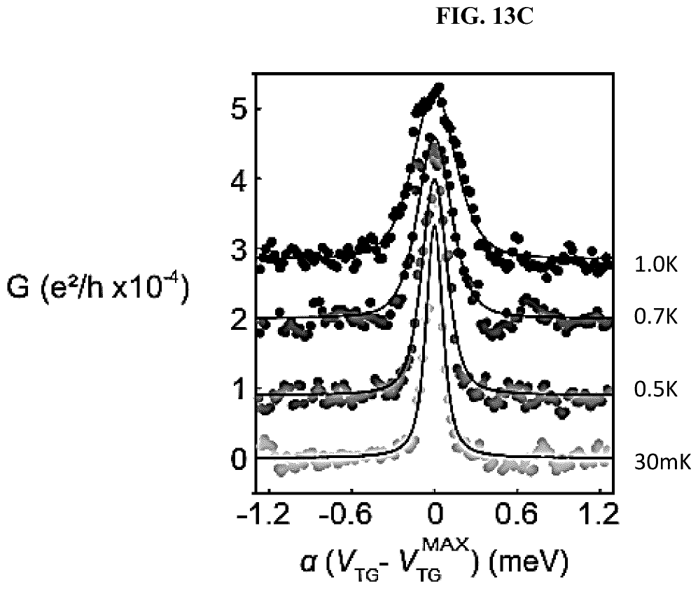

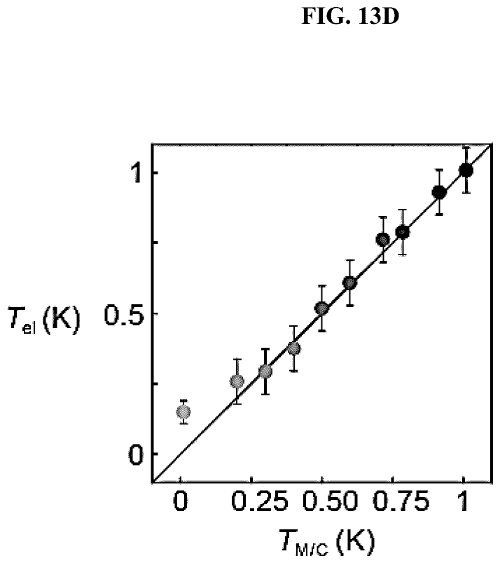

The transfer curves measured at different temperatures are plotted in FIG. 13A. FIG. 13A shows a plot of conductance G (in quantum conductance or e²/h) as a function of gate voltage V_{TG} (in Volts or V) illustrating the channel trans-conductance curves of the transistor according to various embodiments measured at different temperatures.

FIG. 13A shows the typical n-type behavior expected for natural MoS₂, in which doping arises from native point defects such as chalcogen (S) vacancies. The intersection point of the dashed lines in FIG. 13A indicates the threshold voltage (V_{TG}^{th}=1.85V). Near and below threshold (V_{TG}^{th}˜1.78V), a series of sharp conductance peaks may be observed, consistent with Coulomb blockade (CB) in single-charge tunneling. The finite conductance observed sub-threshold at higher temperatures can be shown to arise from variable range hopping within impurity bands, consistent with shallow doping.

FIG. 13B shows plots of the device's differential conductance dI/V in units e²/h×10⁻⁴ as a function of source-drain voltage V_{SD} (in milli electron-Volts or meV) and gate voltage V_{TG} (in volts or V) illustrating finite-bias spectroscopy recorded at a mixing chamber temperature T_{M/C}=30 mK, showing well-defined charge transitions according to various embodiments. The bias spectroscopy confirms signatures of stochastic Coulomb blockade (“Coulomb shards”). The detailed pattern of charge transitions in terms of their number and position in gate-space varies slightly from cool-down to cool-down. Conductance peaks near or above threshold have previously been attributed to point defect ensembles and/or disorder potentials within the conduction band tail. Sub-threshold peaks observed, however, may only be explained by tunneling though impurity-bound states within the bandgap.

As shown by the high-resolution close-ups in FIG. 13B, single-electron tunnelling may be observed through small clusters of defect-bound states in series. However, isolated charged transitions (right panel of FIG. 13B) may also be located, which may be the focus of the investigation as described herein. For the transition shown, symmetric slopes bounding the Coulomb diamond indicate approximately equal capacitive coupling to source and drain reservoirs. Resonances parallel to the diamond edges (as well as parallel to the V_{TG} axis in FIG. 13B, left panel) with splitting of order meV likely reflect orbital excited states and attest to the strong charge confinement present.

FIG. 13C shows a plot of conductance (in quantum conductance or e²/h×10⁻⁴) as a function of voltage difference α (V_{TG}−V_{TG}^{MAX}) (in milli electron-Volts or meV) illustrating the temperature-dependence of a Coulomb blockade peak used to estimate the electron temperature according to various embodiments (data offset for clarity). FIG. 13D shows a plot of electronic temperature Tₑₗ (in Kelvins or K) as a function of mixing chamber temperature T_{M/C} (in Kelvins or K) of the dilution refrigerator used to estimate the lowest electron temperature reached according to various embodiments. An estimate of the effective temperature in the S and D electron reservoirs—and hence our spectral resolution—can be obtained by fitting the Coulomb peaks in FIG. 13C, confirming that tunneling proceeds through individual quantized energy levels, rather than through an electron island in the classical regime. From the fits, Tₑₗ=(150±40)mK is extracted, at the base temperature of the dilution fridge—the lowest reported for Coulomb blockade signatures in TDMC materials to date, and confirming the successful low-temperature contact strategy. The corresponding thermal broadening 3.5 k_{B}T˜45 μeV, together with a finite lifetime broadening Γ˜80 μeV, sets the limit for the spectral resolution in our prototype.

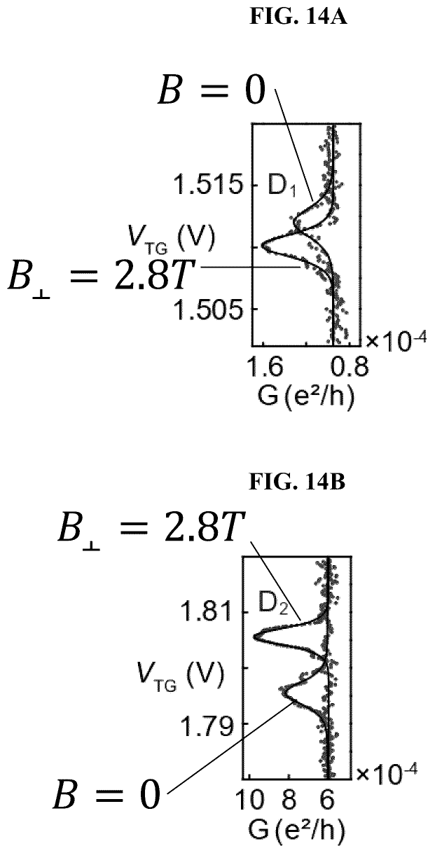

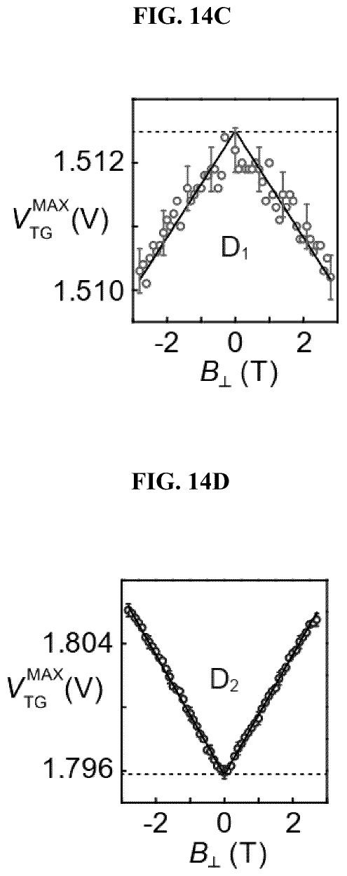

Insight into the interplay of spin and valley in TMDCs can be gained from ground state magnetospectroscopy and measurements of the Zeeman anisotropy, as presented in FIGS. 14A-D.

FIG. 14A is a plot of top gate voltage V_{TG} (in volts or V) as a function of conductance G (in quantum conductance or e²/h) illustrating the Coulomb blockade peaks for transition D₁ at B=0 and B_{⊥}=2.8 T according to various embodiments. FIG. 14B is a plot of top gate voltage V_{TG} (in volts or V) as a function of conductance G (in quantum conductance or e²/h) illustrating the Coulomb blockade peaks for transition D₂ at B=0 and B_{⊥}=2.8 T according to various embodiments. The fitted lines represent the conduction band (CB) peak shape. FIG. 14C is a plot of maximum top gate voltage V_{TG}^{MAX} (in volts or V) as a function of out-of-plane magnetic field B_{⊥} (in tesla or T) illustrating the Zeeman shifted ground state transitions in B_{⊥} for D₁ according to various embodiments. FIG. 14D is a plot of maximum top gate voltage V_{TG}^{MAX} (in volts or V) as a function of out-of-plane magnetic field B_{⊥} (in tesla or T) illustrating the Zeeman shifted ground state transitions in B_{⊥} for D₂ according to various embodiments. The horizontal dashed line in FIG. 14C and FIG. 14D indicates the peak position at B_{⊥}=0.

Detailed insight into the spin-valley nature of these states can only be obtained from a measurement of the g-factor anisotropy in vectorized magnetic fields as shown below. By virtue of the D₃ₕ point group symmetry of the MoS₂ lattice, conduction band electrons are not believed to carry any in-plane magnetic moment within mono- or odd-numbered multi-layers. The resulting pronounced g-factor anisotropy, however, has not yet been experimentally confirmed for individual spin valley states.

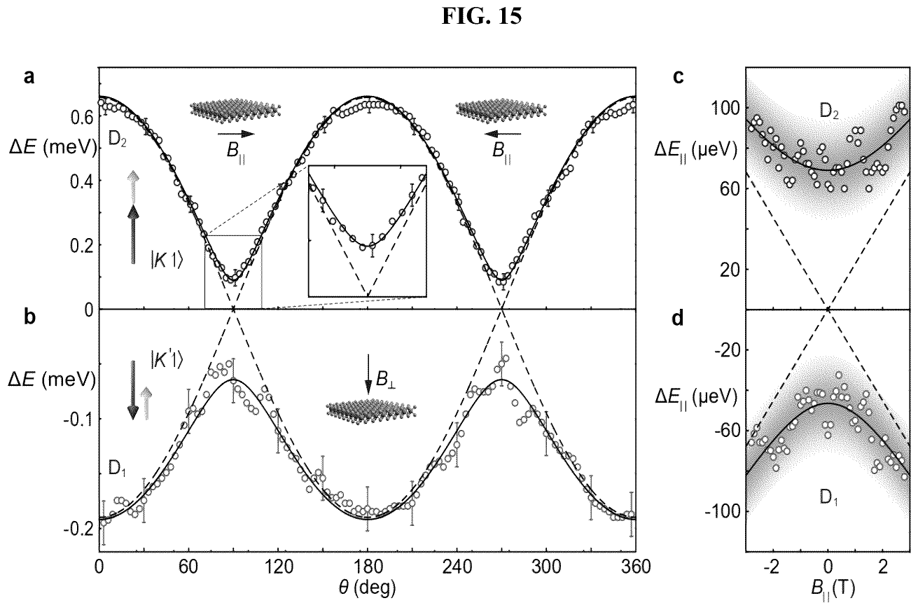

The degree of spin-valley coupling may be quantified from a measurement of the Zeeman anisotropy and a finite in-plane g-factor, consistent across both transitions, as summarized in FIG. 15. FIG. 15 shows (a-b) plots of ground state energy changes (Zeeman shifts) ΔE (in milli electron-volts or meV) as a function of magnetic field orientation θ (in degrees or deg) illustrating anisotropy of the Zeeman shifts of the ground state transition for D₁ and D₂ as a function of magnetic field orientation according to various embodiments; and (c-d) plots of energy transition ΔE_{∥} (in micro electron-volts or μeV) as a function of in-plane magnetic field B_{∥} illustrating shift of the ground state transitions in an in-plane magnetic field B_{∥} according to various embodiments.

The dashed black lines in FIG. 15(a-b) are out-of-plane Zeeman fits as determined, assuming g_{∥}=0, and are seen to underestimate the measured data at in-plane angles θ=90° and 270° for which a finite in-plane Zeeman shift is present. A better representation of the data, including of the pronounced rounding at the minima, can be obtained by considering a finite in-plane g-factor such that

$$Δ {E}^{{s}_{z} , 𝒥} = \pm \frac{1}{2} \sqrt{{( {g}_{⊥} {μ}_{B} B cos θ )}^{2} + {( {g}_{‖} {μ}_{B} B sin θ )}^{2} + {( 2 Δ )}^{2}} \qquad ( 8 )$$

Solid black lines in FIG. 15(a-b) fit to Equation (8). As shown by the solid black lines, fits to Equation (8) allow extraction of comparable values g_{∥}=0.6±0.1(D₁) and g_{∥}=0.8±0.1(D₂) for the two transitions. Consistent g_{∥} can also be confirmed directly from the in-plane Zeeman shifts of D₁ and D₂ ground states as shown in FIG. 15(c-d). Solid black lines here are fitted to:

$$Δ {E}_{‖} = \pm \frac{1}{2} \sqrt{{( {g}_{‖} {μ}_{B} {B}_{‖} )}^{2} + {( 2 Δ )}^{2}} \qquad ( 9 )$$

where a splitting Δ²=Δ_{SO}²+Δ_{KK}² has been taken into account. This arises from a combination of spin-orbit coupling (SOC) and inter-valley mixing. From fits to Equation (9), 2Δ=138±6 μeV(D₂) and 2Δ=93±6 μeV(D₁) are extracted, just within the spectral resolution limit of measurement (80 μeV at 160 mK), while confirming g_{∥}=0.8±0.1 for both transitions in agreement with FIG. 15(a-b). The shaded bands in FIG. 15(c-d) indicate standard deviation (25 μeV) of the distribution of data points around their mean.

The references cited in FIGS. 6A-B are:
1. B. W. Baugher, H. O. Churchill, Y. Yang, and P. Jarillo-Herrero, “Intrinsic electronic transport properties of high-quality monolayer and bilayer MoS₂,” Nano letters, vol. 13, no. 9, pp. 4212-4216, 2013.
2. S. Xu, Z. Wu, H. Lu, Y. Han, G. Long, X. Chen, T. Han, W. Ye, Y. Wu, J. Lin, et al., “Universal low-temperature ohmic contacts for quantum transport in transition metal dichalcogenides,” 2D Materials, vol. 3, no. 2, p. 021007, 2016.
3. Z. Cao, F. Lin, G. Gong, H. Chen, and J. Martin, “Low schottky barrier contacts to 2H-MoS₂ by Sn electrodes,” Applied Physics Letters, vol. 116, no. 2, p. 022101, 2020.
4. Y. Wang, J. C. Kim, R. J. Wu, J. Martinez, X. Song, J. Yang, F. Zhao, A. Mkhoyan, H. Y. Jeong, and M. Chhowalla, “Van der waals contacts between three-dimensional metals and two-dimensional semiconductors,” Nature, vol. 568, no. 7750, pp. 70-74, 2019.
5. B.-K. Kim, T.-H. Kim, D.-H. Choi, H. Kim, K. Watanabe, T. Taniguchi, H. Rho, J.-J. Kim, Y.-H. Kim, and M.-H. Bae, “Origins of genuine ohmic van der waals contact between indium and MoS₂,” npj 2D Materials and Applications, vol. 5, no. 1, pp. 1-10, 2021.
6. K. K. Smithe, C. D. English, S. V. Suryavanshi, and E. Pop, “Intrinsic electrical transport and performance projections of synthetic monolayer MoS₂ devices,” 2D Materials, vol. 4, no. 1, p. 011009, 2016.
7. X. Cui, G.-H. Lee, Y. D. Kim, G. Arefe, P. Y. Huang, C.-H. Lee, D. A. Chenet, X. Zhang, L. Wang, F. Ye, et al., “Multi-terminal transport measurements of MoS₂ using a van der waals heterostructure device platform,” Nature nanotechnology, vol. 10, no. 6, pp. 534-540, 2015.
8. P.-C. Shen, C. Su, Y. Lin, A.-S. Chou, C.-C. Cheng, J.-H. Park, M.-H. Chiu, A.-Y. Lu, H.-L. Tang, M. M. Tavakoli, et al., “Ultralow contact resistance between semimetal and monolayer semiconductors,” Nature, vol. 593, no. 7858, pp. 211-217, 2021.
9. R. Pisoni, Z. Lei, P. Back, M. Eich, H. Overweg, Y. Lee, K. Watanabe, T. Taniguchi, T. Ihn, and K. Ensslin, “Gate-tunable quantum dot in a high quality single layer MoS₂ van der waals heterostructure,” Applied Physics Letters, vol. 112, no. 12, p. 123101, 2018.
10. Z. Wu, S. Xu, H. Lu, A. Khamoshi, G.-B. Liu, T. Han, Y. Wu, J. Lin, G. Long, Y. He, et al., “Even-odd layer-dependent magnetotransport of high-mobility q-valley electrons in transition metal disulfides,” Nature communications, vol. 7, no. 1, pp. 1-8, 2016.
11. R. Pisoni, A. Kormányos, M. Brooks, Z. Lei, P. Back, M. Eich, H. Overweg, Y. Lee, P. Rickhaus, K. Watanabe, et al., “Interactions and magnetotransport through spinvalley coupled landau levels in monolayer MoS₂,” Physical review letters, vol. 121, no. 24, p. 247701, 2018.
12. R. Pisoni, Y. Lee, H. Overweg, M. Eich, P. Simonet, K. Watanabe, T. Taniguchi, R. Gorbachev, T. Ihn, and K. Ensslin, “Gate-defined one-dimensional channel and broken symmetry states in MoS₂ van der waals heterostructures,” Nano letters, vol. 17, no. 8, pp. 5008-5011, 2017.
13. J. Wang, Q. Yao, C.-W. Huang, X. Zou, L. Liao, S. Chen, Z. Fan, K. Zhang, W. Wu, X. Xiao, et al., “High mobility MoS₂ transistor with low schottky barrier contact by using atomic thick h-bn as a tunneling layer,” Advanced materials, vol. 28, no. 37, pp. 8302-8308, 2016.
14. X. Cui, E.-M. Shih, L. A. Jauregui, S. H. Chae, Y. D. Kim, B. Li, D. Seo, K. Pistunova, J. Yin, J.-H. Park, et al., “Low-temperature ohmic contact to monolayer mos2 by van der waals bonded co/h-bn electrodes,” Nano letters, vol. 17, no. 8, pp. 4781-4786, 2017.

1. A transistor comprising:
a substrate;
a first contact electrode over the substrate;
a second contact electrode over the substrate;
a two-dimensional semiconductor material layer above the substrate such that the first contact electrode is in contact with a first portion of the two-dimensional semiconductor material layer and the second contact electrode is in contact with a second portion of the two-dimensional semiconductor material layer;
a first control gate over the two-dimensional semiconductor material layer such that the first portion of the two-dimensional semiconductor material layer is between the first control gate and the first contact electrode;
a second control gate over the two-dimensional semiconductor material layer such that the second portion of the two-dimensional semiconductor material layer is between the second control gate and the second contact electrode;
a main gate over a third portion of the two-dimensional semiconductor material layer, the third portion of the two-dimensional semiconductor material layer between the first portion of the two-dimensional semiconductor material layer and the second portion of the two-dimensional semiconductor material layer; and
a dielectric layer separating the main gate, the first control gate and the second control gate from the two-dimensional semiconductor material layer.

2. The transistor according to claim 1, further comprising:
one or more local gates such that the two-dimensional semiconductor material layer is over the one or more local gates; and
a further dielectric layer in contact with the one or more local gates;
wherein the two-dimensional semiconductor material layer is over the further dielectric layer.

3. The transistor according to claim 2, wherein the dielectric layer and the further dielectric layer comprise an atomically thin insulating crystal material, a high-k dielectric material or a bulk dielectric material.

4. The transistor according to claim 1, wherein the two-dimensional semiconductor material layer comprises one or more monolayers of a suitable two-dimensional semiconductor material.

5. The transistor according to claim 4, wherein the suitable two-dimensional semiconductor material is a transition-metal dichalcogenide material, graphene, a Group III-Group V chalcogenide material, or phosphorene.

6. The transistor according to claim 5,
wherein the suitable two-dimensional semiconductor material is the transition-metal dichalcogenide material; and
wherein the transition-metal dichalcogenide material is molybdenum disulfide (MoS₂), tungsten diselenide (WSe₂), molybdenum diselenide (MoSe₂), tungsten disulfide (WS₂), rhemium diselenide (ReSe₂) or rhemium disulfide (ReS₂).

7. The transistor according to claim 1, wherein the main gate is arranged laterally between the first control gate and the second control gate.

8. The transistor according to claim 1,
wherein a first portion of the main gate is over a portion of the first control gate; and
wherein a second portion of the main gate is over a portion of the second control gate.

9. The transistor according to claim 8, further comprising:
an embedding dielectric layer such that the main gate, the first control gate and the second control gate are in contact with the embedding dielectric layer;
wherein a first portion of the embedding dielectric layer separates the main gate from the first control gate; and
wherein a second portion of the embedding dielectric layer separates the main gate from the second control gate.

10. The transistor according to claim 1,
wherein a portion of the first control gate is over a first portion of the main gate; and
wherein a portion of the second control gate is over a second portion of the main gate.

11. The transistor according to claim 10, further comprising:
an embedding dielectric layer such that the main gate, the first control gate and the second control gate are in contact with the embedding dielectric layer;
wherein a first portion of the embedding dielectric layer separates the main gate from the first control gate; and
wherein a second portion of the embedding dielectric layer separates the main gate from the second control gate.

12. A method of forming a transistor, the method comprising:
forming a first contact electrode over a substrate;
forming a second contact electrode over the substrate;
forming a two-dimensional semiconductor material layer above the substrate such that the first contact electrode is in contact with a first portion of the two-dimensional semiconductor material layer and the second contact electrode is in contact with a second portion of the two-dimensional semiconductor material layer;
forming a first control gate over the two-dimensional semiconductor material layer such that the first portion of the two-dimensional semiconductor material layer is between first control gate and the first contact electrode;
forming a second control gate over the two-dimensional semiconductor material layer such that the second portion of the two-dimensional semiconductor material layer is between second control gate and the second contact electrode;
forming a main gate over a third portion of the two-dimensional semiconductor material layer, the third portion of the two-dimensional semiconductor material layer between the first portion of the two-dimensional semiconductor material layer and the second portion of the two-dimensional semiconductor material layer; and
forming a dielectric layer separating the main gate, the first control gate and the second control gate from the two-dimensional semiconductor material layer.

13. The method according to claim 12, further comprising:
forming one or more local gates such that the two-dimensional semiconductor material layer is over the one or more local gates; and
forming a further dielectric layer in contact with the one or more local gates;
wherein the two-dimensional semiconductor material layer is over the further dielectric layer.

14-18. (canceled)

19. The method according to claim 12,
wherein a first portion of the main gate is over a portion of the first control gate; and
wherein a second portion of the main gate is over a portion of the second control gate.

20. The method according to claim 19, further comprising:
forming an embedding dielectric layer such that the main gate, the first control gate and the second control gate are in contact with the embedding dielectric layer;
wherein a first portion of the embedding dielectric layer separates the main gate from the first control gate; and
wherein a second portion of the embedding dielectric layer separates the main gate from the second control gate.

21. The method according to claim 12,
wherein a portion of the first control gate is over a first portion of the main gate; and
wherein a portion of the second control gate is over a second portion of the main gate.

22. The method according to claim 21, further comprising:
forming an embedding dielectric layer such that the main gate, the first control gate and the second control gate are in contact with the embedding dielectric layer;
wherein a first portion of the embedding dielectric layer separates the main gate from the first control gate; and
wherein a second portion of the embedding dielectric layer separates the main gate from the second control gate.

23. The method according to claim 12, wherein the first contact electrode and the second contact electrode are formed in a same lithographic step.

24. The method according to claim 12, wherein the dielectric layer is formed before forming the main gate, the first control gate and the second control gate.

25. The method according to claim 12, wherein the first control gate and the second control gate are formed in a same lithographic step.
